(19) United States
(12) Patent Application Publication
(10) Pub. No.: US 2026/0173813 A1
(43) Pub. Date: Jun. 18, 2026

(54) LIQUID SURFACE PROTECTIVE MATERIAL FOR SEMICONDUCTOR WAFER PROCESSING

(71) Applicant: NITTO DENKO CORPORATION, Ibaraki-shi, Osaka (JP)

(72) Inventors: Takeshi IGARASHI, Ibaraki-shi (JP); Nao KIRIYAMA, Ibaraki-shi (JP); Keita MIKI, Ibaraki-shi (JP); Koki HASHIMOTO, Ibaraki-shi (JP)

(73) Assignee: NITTO DENKO CORPORATION, Ibaraki-shi, Osaka (JP)

(21) Appl. No.: 19/128,749

(22) PCT Filed: Aug. 28, 2023
(86) PCT No.: PCT/JP2023/030950

§ 371 Date: May 9, 2025

(30) Foreign Application Priority Data
Nov. 28, 2022 (JP) 2022-189164

(51) Int. Cl. H10P 72/70; H10P 52/00

(52) U.S. Cl. CPC H10P 72/7404; H10P 72/7422; H10P 72/7442; H10P 52/00

(57) ABSTRACT

Provided is a liquid surface protective material for semiconductor wafer processing, which is excellent in property of embedding a semiconductor wafer surface, and in which an adhesive residue (adhesion of a residue of the surface protective material) on the semiconductor wafer surface after the peeling can be suppressed. The liquid surface protective material for semiconductor wafer processing includes an acrylic emulsion resin. In addition, a protective film is formed of the liquid surface protective material for semiconductor wafer processing. A method of processing a semiconductor wafer includes: applying a liquid surface protective material for semiconductor wafer processing to a surface of the semiconductor wafer on which a circuit pattern is formed, to form a protective film; grinding a surface of the semiconductor wafer on which the protective film is not formed; and peeling off and removing the protective film.

### TECHNICAL FIELD

The present invention relates to a liquid surface protective material for semiconductor wafer processing, a protective film formed of a liquid surface protective material for semiconductor wafer processing, and a method of processing a semiconductor wafer.

### BACKGROUND ART

A semiconductor wafer is subjected to a processing process such as a backgrinding step under a state in which a surface on which a circuit is formed is protected with a protective material. A pressure-sensitive adhesive tape has been known as a typical protective material of the semiconductor wafer (for example, Patent Literature 1). In recent years, the circuit surface of the semiconductor wafer has become complicated, and hence unevenness of the circuit surface may not be able to be sufficiently embedded with the pressure-sensitive adhesive tape. When the embedding is insufficient, water enters a space between a pressure-sensitive adhesive layer of the pressure-sensitive adhesive tape and a semiconductor wafer surface, and chip fly and cracks may occur. In addition, a foreign matter may adhere to a portion in which embedding is insufficient.

A method of applying a liquid composition to form a protective film has been proposed as a method of protecting the circuit surface of the semiconductor wafer except using the pressure-sensitive adhesive tape (for example, Patent Literatures 2 to 6). However, in the protective film formed by each of those methods, a residue adheres to the circuit surface after the removal of the protective film, and hence contamination of the circuit surface by the protective film may occur. In addition, a removing step with a solvent may be required as a removing step, and hence an environmental load may increase.

### CITATION LIST

### Patent Literature

[PTL 1] JP 2015-185641 A
[PTL 2] JP 10-120965 A
[PTL 3] JP 2000-315668 A
[PTL 4] JP 2014-212179 A
[PTL 5] JP 2011-23272 A
[PTL 6] JP 2014-19889 A

### SUMMARY OF INVENTION

### Technical Problem

The present invention has been made to solve the above-mentioned problems of the related art, and an object of the present invention is to provide a liquid surface protective material for semiconductor wafer processing, which is excellent in property of embedding a semiconductor wafer surface, and in which an adhesive residue (adhesion of a residue of the surface protective material) on the semiconductor wafer surface after peeling can be suppressed.

### Solution to Problem

1. According to an embodiment of the present invention, there is provided a surface protective material for semiconductor wafer processing, including an acrylic emulsion resin.

2. In the liquid surface protective material for semiconductor wafer processing according to the above-mentioned item 1, the acrylic emulsion resin may have an acid value of 10 mg/KOH or less.

3. In the liquid surface protective material for semiconductor wafer processing according to the above-mentioned item 1 or 2, the acrylic emulsion resin may have a SP value of from 9 (cal/cm³)^{1/2} to 11 (cal/cm³)^{1/2}.

4. In the liquid surface protective material for semiconductor wafer processing according to any one of the above-mentioned items 1 to 3, the liquid surface protective material for semiconductor wafer processing may have a BH viscosity of from 0.1 Pa·s to 10 Pa·s.

5. According to another aspect of the embodiment of the present invention, there is provided a protective film. The protective film is formed by using the liquid surface protective material for semiconductor wafer processing of any one of the above-mentioned items 1 to 4.

6. In the protective film according to the above-mentioned item 5, the protective film may have a tensile modulus of elasticity at 23° C. of from 0.1 GPa to 1.1 GPa.

7. In the protective film according to the above-mentioned item 5 or 6, the protective film may have a pressure-sensitive adhesive strength to a silicon wafer of 1.0 N/25 mm or less.

8. According to still another aspect of the embodiment of the present invention, there is provided a method of processing a semiconductor wafer. The method of processing a semiconductor wafer includes: applying the liquid surface protective material for semiconductor wafer processing of any one of the above-mentioned items 1 to 4 to a surface of a semiconductor wafer on which a circuit pattern is formed, to form a protective film; grinding a surface of the semiconductor wafer on which the protective film is not formed; and peeling off and removing the protective film.

### Advantageous Effects of Invention

According to the embodiments of the present invention, there is provided the liquid surface protective material for semiconductor wafer processing, which is excellent in property of embedding a semiconductor wafer surface (more specifically, a circuit surface), and in which an adhesive residue (adhesion of a residue of the surface protective material) on the semiconductor wafer surface after peeling of a protective film can be suppressed. Further, the protective film formed by using the liquid surface protective material for semiconductor wafer processing of the embodiment of the present invention can be peeled off and removed, and does not require a removing step with a solvent. Accordingly, an environmental load through use of the solvent can be reduced. Further, the adhesive residue (adhesion of a residue of the surface protective material) on the semiconductor wafer surface after the peeling can be suppressed.

### BRIEF DESCRIPTION OF DRAWINGS

FIG. 1 are each a schematic sectional view of a semiconductor wafer and a protective film in a semiconductor wafer processing process of an embodiment of the present invention.

FIG. 2 are each a schematic sectional view of a semiconductor wafer and a protective film in a semiconductor wafer processing process of another embodiment of the present invention.

FIG. 3 are each a schematic sectional view of a semiconductor wafer and a protective film in a semiconductor wafer processing process of still another embodiment of the present invention.

### DESCRIPTION OF EMBODIMENTS

### A. Liquid Surface Protective Material for Semiconductor Wafer Processing

A liquid surface protective material for semiconductor wafer processing (hereinafter also referred to as “liquid surface protective material”) of an embodiment of the present invention includes an acrylic emulsion resin. The liquid surface protective material of the embodiment of the present invention is used by being applied to, for example, a circuit surface of a semiconductor wafer. The shape of the circuit surface of the semiconductor wafer has become complicated, and hence a surface protective material more excellent in embedding property has been required in order to appropriately protect the circuit surface in a processing process for the semiconductor wafer. The surface protective material of the embodiment of the present invention is a liquid, and hence can be excellent in property of embedding the surface of the semiconductor wafer (more specifically, the circuit surface) even when the circuit surface of the semiconductor wafer has a complicated shape. In addition, a protective film formed of the liquid surface protective material of the embodiment of the present invention can be easily removed by peeling. Accordingly, a dissolving and removing step with a solvent is not required, and hence an environmental load caused by the solvent can be reduced. Further, an adhesive residue (adhesion of a residue of the surface protective material) on a semiconductor wafer surface can be suppressed.

A BH viscosity of the liquid surface protective material of the embodiment of the present invention is preferably from 0.1 Pa·s to 10 Pa·s, more preferably from 0.2 Pa·s to 5 Pa·s, still more preferably from 0.3 Pa·s to 3 Pa·s, particularly preferably from 0.5 Pa·s to 2 Pa·s. When the BH viscosity falls within the above-mentioned ranges, the liquid surface protective material can be satisfactorily applied to the semiconductor wafer surface. The BH viscosity may be adjusted to any appropriate value in accordance with an application method. Herein, the term “BH viscosity” refers to a viscosity measured with a BH-type viscometer under the conditions of 30° C. and 2 rpm. Any appropriate rotor may be used as a rotor to be used in the measurement in accordance with the viscosity, and, for example, No. 2 rotor may be used.

### A-1. Acrylic Emulsion Resin

A resin obtained by subjecting any appropriate monomer component to emulsion polymerization may be used as the acrylic emulsion resin. As described above, the liquid surface protective material of the embodiment of the present invention includes the acrylic emulsion resin. The protective film is formed on the semiconductor wafer surface by drying the liquid surface protective material including the acrylic emulsion resin after its application. The protective film appropriately protects the surface of the semiconductor wafer in the processing process for the semiconductor wafer, and can be peeled off and removed without being dissolved with the solvent after being used. Further, an adhesive residue (adhesion of a residue of the surface protective material) on the semiconductor wafer surface after the peeling can be suppressed. A wide variety of kinds of monomers are available for the acrylic emulsion resin, and a liquid surface protective material capable of forming a protective film having appropriate physical properties can be obtained by selecting the kinds of monomers to be copolymerized.

An acid value of the acrylic emulsion resin is preferably 10 mg/KOH or less, more preferably from 0 mg/KOH to 8 mg/KOH, still more preferably from 0 mg/KOH to 5 mg/KOH, particularly preferably from 0 mg/KOH to 3 mg/KOH. When the acid value of the acrylic emulsion resin falls within the above-mentioned ranges, peeling workability (e.g., suppression of the occurrence of tear and chipping of the protective film at the time of peeling) of the protective film formed of the liquid surface protective material is improved, and hence the protective film can be easily peeled from the semiconductor wafer surface. Herein, the term “acid value of the acrylic emulsion resin” refers to a value measured in conformity with a potentiometric titration method specified in JIS K 0070:1992.

A SP value of the acrylic emulsion resin is preferably from 9 (cal/cm³)^{1/2} to 11 (cal/cm³)^{1/2}, more preferably from 9 (cal/cm³)^{1/2} to 10.8 (cal/cm³)^{1/2}, still more preferably from 9 (cal/cm³)^{1/2} to 10.5 (cal/cm³)^{1/2}. When the SP value falls within the above-mentioned ranges, the occurrence of a peeling failure caused by an excessive increase in pressure-sensitive adhesive strength to the semiconductor wafer surface of the protective film formed of the liquid surface protective material, and adhesion of a residue of the surface protective material to the semiconductor wafer surface can be suppressed. Herein, the term “SP value” refers to a value of a solubility parameter calculated from a basic structure of a compound by a method proposed by Fedors.

A glass transition temperature (Tg) of the acrylic emulsion resin may be set to any appropriate value. The glass transition temperature of the acrylic emulsion resin is preferably from −30° C. to 30° C., more preferably from −25° C. to 25° C., still more preferably from −20° C. to 20° C. When the Tg of the acrylic emulsion resin falls within the above-mentioned ranges, the adhesiveness of the protective film formed of the liquid surface protective material to the semiconductor wafer is improved, and hence a liquid surface protective material more excellent in embedding property can be provided. Herein, the term “glass transition temperature of the acrylic emulsion resin” refers to a theoretical value calculated by Fox's equation from monomer units for forming each resin (polymer) and ratios thereof. The theoretical glass transition temperature determined by Fox's equation may be consistent with an actually measured glass transition temperature determined by a method, such as differential scanning calorimetry (DSC) or dynamic viscoelasticity measurement. When the theoretical value cannot be calculated, the actually measured glass transition temperature may be used.

As described below, Fox's equation is a relational equation between the Tg of an acrylic polymer and the glass transition temperature Tgi of a homopolymer obtained by homopolymerizing each of monomers for forming the acrylic polymer:

$$1 / Tg = \sum ( Wi / Tgi )$$

where Tg represents the glass transition temperature (unit: K) of the acrylic polymer, Wi represents the weight fraction (copolymerization ratio on a weight basis) of a monomer “i” in the acrylic polymer, and Tgi represents the glass transition temperature (unit: K) of the homopolymer of the monomer “i”.

A value described in any appropriate material may be used as the glass transition temperature of the homopolymer to be used in the calculation of the Tg. For example, for monomers listed below, the following values are used as glass transition temperatures of the homopolymers of the monomers.

| | | |
|---|---|---|
| n-Butyl acrylate | −55° | C. |
| Acrylonitrile | 97° | C. |
| Methyl methacrylate | 105° | C. |
| Acrylic acid | 106° | C. |
| Vinyl acetate | 32° | C. |

A numerical value described in, for example, “Polymer Handbook” (3rd edition, John Wiley & Sons, Inc., 1989) may be used as the glass transition temperature of the homopolymer of a monomer except those listed above. When a plurality of kinds of values are described, the highest value is adopted.

A value (actually measured glass transition temperature) obtained by a measurement method as described in JP 2007-51271 A may be used for such a monomer that the glass transition temperature of a homopolymer thereof is not described in the above-mentioned Polymer Handbook. Specifically, 100 parts by weight of the monomer, 0.2 part by weight of azobisisobutyronitrile, and 200 parts by weight of ethyl acetate serving as a polymerization solvent are loaded into a reactor including a temperature gauge, a stirring machine, a nitrogen-introducing tube, and a reflux condenser, and are stirred for 1 hour while a nitrogen gas is flowed in the reactor. After oxygen in a polymerization system has been removed as described above, a temperature in the reactor is increased to 63° C. and the mixture is subjected to a reaction for 10 hours. Next, the resultant is cooled to room temperature to provide a homopolymer solution having a solid content concentration of 33 wt %. Next, the homopolymer solution is cast onto a release liner, and is dried to produce a test sample having a thickness of about 2 mm (sheet-shaped homopolymer). The test sample is punched into a disc shape having a diameter of 7.9 mm. The disc is sandwiched between parallel plates, and its viscoelasticity is measured with a viscoelasticity tester (ARES, manufactured by Rheometric Scientific, Inc.) in the temperature region of from −70° C. to 150° C. at a rate of temperature increase of 5° C./min by a shear mode while a shear strain having a frequency of 1 Hz is applied to the disc. The peak top temperature of the tanδ of the disc is defined as the Tg of the homopolymer.

### A-1-1. Monomer Composition

As described above, the acrylic emulsion resin is obtained by subjecting any appropriate monomer composition to emulsion polymerization. The monomer composition contains a (meth)acrylic monomer and/or any appropriate monomer copolymerizable with the (meth)acrylic monomer. The monomer component may contain only one kind of monomer, or two or more kinds of monomers may be used in combination. Herein, the term “(meth)acrylic” refers to acrylic and/or methacrylic.

Typically, the monomer composition preferably contains a (meth)acryloyl group-containing monomer. The (meth)acryloyl group-containing monomers may be used alone or in combination thereof. A content ratio of the (meth)acryloyl group-containing monomer is preferably 40 parts by weight or more, more preferably 60 parts by weight or more, still more preferably 65 parts by weight or more, particularly preferably 70 parts by weight or more with respect to 100 parts by weight of a total of all monomer components. The content of the (meth)acryloyl group-containing monomer is, for example, 95 parts by weight or less with respect to 100 parts by weight of the total of all the monomer components. When the content ratio of the (meth)acryloyl group-containing monomer falls within the above-mentioned ranges, the protective film formed of the liquid surface protective material can be peeled off and removed, and an adhesive residue (adhesion of a residue of the surface protective material) on the semiconductor wafer surface can be suppressed.

Any appropriate (meth)acryloyl group-containing monomer is used as the (meth)acryloyl group-containing monomer. An alkyl (meth)acrylate is preferably used as the (meth)acryloyl group-containing monomer. When the kind and/or content ratio of the alkyl (meth)acrylate to be used is adjusted, for example, the storage modulus of elasticity of the liquid surface protective material, the SP value of the acrylic emulsion resin, and the tensile characteristics of the protective film to be formed may be adjusted to any appropriate values. The alkyl (meth)acrylates may be used alone or in combination thereof.

Any appropriate alkyl (meth)acrylate may be used as the alkyl (meth)acrylate. Specific examples thereof include alkyl (meth)acrylates each having an alkyl group having 1 to 20 carbon atoms (hereinafter also referred to as “C1 to C20 alkyl (meth)acrylates”), such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, hexyl (meth)acrylate, heptyl (meth)acrylate, octyl (meth)acrylate, 2-ethylhexyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate.

The monomer composition preferably contains an alkyl (meth)acrylate having an alkyl group having 4 to 20 carbon atoms (C4 to C20 alkyl (meth)acrylate), more preferably contains an alkyl (meth)acrylate having an alkyl group having 4 to 14 carbon atoms, and still more preferably contains an alkyl (meth)acrylate having an alkyl group having 4 to 9 carbon atoms. When those alkyl (meth)acrylates are used, peeling of the protective film formed by using the liquid surface protective material can be easily performed. Further, an adhesive residue (adhesion of a residue of the surface protective material) on the semiconductor wafer surface after the peeling can be suppressed. Specifically, the monomer composition preferably contains n-butyl acrylate (BA) and/or 2-ethylhexyl acrylate (2EHA), and more preferably contains BA. The C4 to C20 alkyl (meth)acrylates may be used alone or in combination thereof.

In the monomer composition, the C4 to C20 alkyl (meth)acrylate may be used at any appropriate content ratio. A content ratio of the C4 to C20 alkyl (meth)acrylate is preferably 40 parts by weight or more, more preferably 60 parts by weight or more, still more preferably 65 parts by weight or more with respect to 100 parts by weight of the total of all the monomer components. When the content ratio of the C4 to C20 alkyl (meth)acrylate falls within the above-mentioned ranges, peeling of the protective film formed by using the liquid surface protective material can be easily performed. In addition, the pressure-sensitive adhesive strength to the semiconductor wafer surface may be adjusted to an appropriate value, and hence damage to the semiconductor wafer surface at the time of the peeling can be suppressed.

The monomer composition preferably further contains a nitrogen atom-containing monomer. Any appropriate nitrogen atom-containing monomer may be used as the nitrogen atom-containing monomer. Specific examples thereof include: cyano group-containing monomers, such as acrylonitrile, methacrylonitrile, and 2-cyanoethyl (meth)acrylate; amide group-containing monomers, such as (meth)acrylamide, N,N-dimethyl (meth)acrylamide, N-butyl (meth)acrylamide, N-methylol (meth)acrylamide, N-hydroxyethyl (meth)acrylamide, N-methoxymethyl (meth)acrylamide, N-butoxymethyl (meth)acrylamide, and diacetone (meth)acrylamide; amino group-containing monomers, such as aminoethyl (meth)acrylate, N,N-dimethylaminoethyl (meth)acrylate, and t-butylaminoethyl (meth)acrylate; and monomers each having a nitrogen atom-containing ring, such as N-vinyl-2-pyrrolidone, N-methylvinylpyrrolidone, N-vinylpyridine, N-vinylpiperidone, N-vinylpyrimidine, N-vinylpiperazine, N-vinylpyrazine, N-vinylpyrrole, N-vinylimidazole, N-vinyloxazole, N-vinylmorpholine, N-vinylcaprolactam, and N-(meth)acryloylmorpholine. The nitrogen atom-containing monomer is preferably a cyano group-containing monomer, more preferably acrylonitrile. When an acrylic emulsion resin obtained by using a monomer composition containing each of those nitrogen atom-containing monomers is used, peeling of the protective film formed by using the liquid surface protective material can be easily performed, and hence damage to the semiconductor wafer surface can be suppressed. In addition, the Tg and SP value of the acrylic emulsion resin to be obtained may be satisfactorily adjusted to any values. The nitrogen atom-containing monomers may be used alone or in combination thereof.

In the monomer composition, the nitrogen atom-containing monomer may be used at any appropriate content ratio. A content ratio of the nitrogen atom-containing monomer is preferably 10 parts by weight or more, more preferably 15 parts by weight or more, still more preferably 20 parts by weight or more, particularly preferably 25 parts by weight or more with respect to 100 parts by weight of the total of all the monomer components. When the content ratio of the nitrogen atom-containing monomer falls within the above-mentioned ranges, peeling of the protective film formed by using the liquid surface protective material can be easily performed. Further, an adhesive residue (adhesion of a residue of the surface protective material) on the semiconductor wafer surface after the peeling can be reduced. The content ratio of the nitrogen atom-containing monomer is preferably 50 parts by weight or less with respect to 100 parts by weight of the total of all the monomer components.

The monomer composition preferably further contains an alkyl (meth)acrylate having an alkyl group having 1 to 3 carbon atoms (C1 to C3 alkyl (meth)acrylate). When the monomer composition further containing each of those alkyl (meth)acrylates is used, peeling of the protective film formed by using the liquid surface protective material can be easily performed, and hence damage to the semiconductor wafer surface can be suppressed. Methyl methacrylate (MMA) or ethyl methacrylate is preferably used as the C1 to C3 alkyl (meth)acrylate. The C1 to C3 alkyl (meth)acrylates may be used alone or in combination thereof.

In the monomer composition, the C1 to C3 alkyl (meth)acrylate may be used at any appropriate content ratio. A content ratio of the C1 to C3 alkyl (meth)acrylate is preferably 6 parts by weight or more, more preferably 8 parts by weight or more, still more preferably 10 parts by weight or more, particularly preferably 15 parts by weight or more with respect to 100 parts by weight of the total of all the monomer components. When the content ratio of the C1 to C3 alkyl (meth)acrylate falls within the above-mentioned ranges, peeling of the protective film formed by using the liquid surface protective material can be easily performed, and hence damage to the semiconductor wafer surface at the time of the peeling can be suppressed. The content ratio of the C1 to C3 alkyl (meth)acrylate is, for example, 50 parts by weight or less with respect to 100 parts by weight of the total of all the monomer components.

The monomer composition may further contain any appropriate other monomer component. Specific examples of the other monomer component include functional group-containing monomers including: carboxy group-containing monomers, such as acrylic acid (AA), methacrylic acid (MAA), carboxyethyl (meth)acrylate, carboxypentyl (meth)acrylate, itaconic acid, maleic acid, fumaric acid, crotonic acid, and isocrotonic acid; hydroxyalkyl (meth)acrylates, such as 2-hydroxyethyl (meth)acrylate, 2-hydroxypropyl (meth)acrylate, 3-hydroxypropyl (meth)acrylate, 2-hydroxybutyl (meth)acrylate, and 4-hydroxybutyl (meth)acrylate, and hydroxy group (OH group)-containing monomers such as polypropylene glycol mono(meth)acrylate; acid anhydride group-containing monomers, such as maleic anhydride and itaconic anhydride; epoxy group-containing monomers, such as glycidyl (meth)acrylate, methyl glycidyl (meth)acrylate, and allyl glycidyl ether; keto group-containing monomers, such as diacetone (meth)acrylate, vinyl methyl ketone, vinyl ethyl ketone, allyl acetoacetate, and vinyl acetoacetate; and alkoxysilyl group-containing monomers, such as 3-(meth)acryloxypropyltrimethoxysilane, 3-(meth)acryloxypropyltriethoxysilane, 3-(meth)acryloxypropylmethyldimethoxysilane, and 3-(meth)acryloxypropylmethyldiethoxysilane. When the functional group-containing monomer is further incorporated, cohesive strength of the acrylic emulsion resin can be improved. Further, the tensile characteristics of the formed protective film and the SP value of the acrylic emulsion resin may be adjusted to any appropriate values.

The monomer composition may further contain any other copolymerizable component except the above-mentioned monomer for the purpose of, for example, an improvement in cohesive strength. Examples of the other copolymerized component include: vinyl ester-based monomers, such as vinyl acetate (VAc), vinyl propionate, and vinyl laurate; aromatic vinyl compounds, such as styrene, substituted styrene (e.g., α-methylstyrene), and vinyltoluene; cycloalkyl (meth)acrylates, such as cyclohexyl (meth)acrylate, cyclopentyl (meth)acrylate, and isobornyl (meth)acrylate; aromatic ring-containing (meth)acrylates, such as an aryl (meth)acrylate (e.g., phenyl (meth)acrylate), an aryloxyalkyl (meth)acrylate (e.g., phenoxy ethyl (meth)acrylate), and an arylalkyl (meth)acrylate (e.g., benzyl (meth)acrylate); olefin-based monomers, such as ethylene, propylene, isoprene, butadiene, and isobutylene; chlorine atom-containing monomers, such as vinyl chloride and vinylidene chloride; alkoxy group-containing monomers, such as methoxyethyl (meth)acrylate, ethoxyethyl (meth)acrylate, and ethyl carbitol (meth)acrylate; vinyl ether-based monomers, such as methyl vinyl ether and ethyl vinyl ether; and polyfunctional monomers each having 2 or more (e.g., 3 or more) polymerizable functional groups (e.g., (meth)acryloyl groups) in one molecule, such as 1,6-hexanediol di(meth)acrylate and trimethylolpropane tri(meth)acrylate.

The other monomer component and the other copolymerizable component are used at any appropriate content ratios. For example, in the monomer composition, the components are used so that the total amount of the C4 to C20 alkyl (meth)acrylate, the nitrogen atom-containing monomer, and the C1 to C3 alkyl (meth)acrylate may become 100 parts by weight.

### A-1-2. Synthesis of Acrylic Emulsion Resin

The acrylic emulsion resin is obtained by subjecting the above-mentioned monomer composition to emulsion polymerization. A monomer supply system in the emulsion polymerization may be a collective loading system involving supplying the entire monomer raw material in one stroke, may be a continuous supply (dropping) system, or may be a divided supply (dropping) system. In addition, part or whole of the monomer component may be emulsified by being mixed with water and an emulsifier in advance, and the emulsion may be supplied to a polymerization vessel.

A polymerization temperature may be set to any appropriate value in accordance with, for example, the kinds of the monomer and solvent to be used or the kind of the polymerization initiator. The polymerization temperature is, for example, 20° C. or more, preferably 40° C. or more, more preferably 50° C. or more. In addition, the polymerization temperature is preferably 95° C. or less, more preferably 85° C. or less.

Any appropriate initiator is used as the polymerization initiator. Examples thereof include: redox-based initiators each based on a combination of an azo-based polymerization initiator, a peroxide-based initiator, or peroxide and a reducing agent; and substituted ethane-based initiators. Specific examples thereof include: azo-based initiators, such as 2,2′-azobisisobutyronitrile, 2,2′-azobis[N-(2-carboxyethyl)-2-methylpropionamidine]hydrate, 2,2′-azobis(2-methylpropionamidine) disulfate, 2,2′-azobis(2-methylpropionamidine) dihydrochloride, 2,2′-azobis(2-methylpropionamidine) dihydrochloride, 2,2′-azobis[2-(5-methyl-2-imdazolin-2-yl) propane]dihydrochloride, and 2,2′-azobis(N,N′-dimethyleneisobutylamidine) dihydrochloride; persulfates, such as potassium persulfate and ammonium persulfate; peroxide-based initiators, such as benzoyl peroxide, t-butyl hydroperoxide, di-t-butyl peroxide, dicumyl peroxide, dilauroyl peroxide, di-n-octanoyl peroxide, di(4-methylbenzoyl) peroxide, t-butyl peroxybenzoate, t-butyl peroxyisobutyrate, t-hexyl peroxypivalate, t-butyl peroxypivalate, di(2-ethylhexyl) peroxydicarbonate, di(4-t-butylcyclohexyl) peroxydicarbonate, di-sec-butyl peroxydicarbonate, t-butyl peroxyneodecanoate, 1,1,3,3-tetramethylbutyl peroxy-2-ethylhexanoate, 1,1-bis(t-butylperoxy)-3,3,5-trimethylcyclohexane, 1,1-bis(t-butylperoxy) cyclododecane, 1,1-bis(t-hexylperoxy)cyclohexane, and hydrogen peroxide; and redox-based initiators, such as a combination of a peroxide and ascorbic acid (e.g., a combination of hydrogen peroxide water and ascorbic acid), a combination of a peroxide and an iron (II) salt (e.g., a combination of hydrogen peroxide water and an iron (II) salt), and a combination of a persulfate and sodium hydrogen sulfite.

The polymerization initiator is used at any appropriate content. The content is, for example, preferably from 0.001 part by weight to 5 parts by weight, more preferably from 0.01 part by weight to 3 parts by weight, still more preferably from 0.01 part by weight to 2 parts by weight with respect to 100 parts by weight of the total of the monomer components.

The emulsion polymerization is typically performed under the presence of an emulsifier. Any appropriate emulsifier may be used as the emulsifier. For example, an anionic emulsifier or a nonionic emulsifier may be used as the emulsifier. The emulsifiers may be used alone or in combination thereof.

Examples of the anionic emulsifier include sodium lauryl sulfate, ammonium lauryl sulfate, sodium dodecylbenzene sulfonate, sodium polyoxyethylene lauryl sulfate, a sodium polyoxyethylene alkyl ether sulfate, an ammonium polyoxyethylene alkyl phenyl ether sulfate, a sodium polyoxyethylene alkyl phenyl ether sulfate, and a sodium polyoxyethylene alkyl sulfosuccinate. Examples of the nonionic emulsifier include a polyoxyethylene alkyl ether, a polyoxyethylene alkyl phenyl ether, a polyoxyethylene fatty acid ester, and a polyoxyethylene polyoxypropylene block polymer. In addition, an emulsifier having a reactive functional group (reactive emulsifier) may be used as the emulsifier. Examples of the reactive emulsifier include radical polymerizable emulsifiers each having a structure obtained by introducing a radical polymerizable functional group, such as a propenyl group or an allyl ether group, to the anionic emulsifier or the nonionic emulsifier.

The emulsifier is used in any appropriate amount. The content of the emulsifier is preferably 0.2 part by weight or more, more preferably 0.5 part by weight or more, still more preferably 1.0 part by weight or more, particularly preferably 1.5 parts by weight or more with respect to 100 parts by weight of the total of the monomer components. Typically, the usage amount of the emulsifier is preferably 10 parts by weight or less, more preferably 5 parts by weight or less, still more preferably 3 parts by weight or less with respect to 100 parts by weight of the total of the monomer components from the viewpoint of suppressing foaming at the time of emulsion polymerization and the foaming of a composition containing the resultant emulsion.

The emulsion polymerization may be performed under the presence of a protective colloid. Examples of the protective colloid include: polyvinyl alcohol-based polymers, such as a partially saponified polyvinyl alcohol, a completely saponified polyvinyl alcohol, and a modified polyvinyl alcohol; cellulose derivatives, such as hydroxyethyl cellulose, hydroxypropyl cellulose, and a carboxymethyl cellulose salt; and natural polysaccharides such as guar gum. The protective colloids may be used alone or in combination thereof.

The saponification degree of the partially saponified polyvinyl alcohol is, for example, less than 95 mol %, preferably less than 92 mol %, more preferably less than 90 mol %. The saponification degree of the partially saponified polyvinyl alcohol is preferably 65 mol % or more, more preferably 70 mol % or more, still more preferably 80 mol % or more, particularly preferably 85 mol % or more from the viewpoint of, for example, the stability of the emulsion. As described above, a completely saponified polyvinyl alcohol may be adopted.

Examples of the modified polyvinyl alcohol include: an anion-modified polyvinyl alcohol having introduced thereinto an anionic group, such as a carboxy group and/or a sulfonate group; and a cation-modified polyvinyl alcohol having introduced thereinto a cationic group such as a quaternary ammonium salt. The saponification degree of the modified polyvinyl alcohol is, for example, less than 98 mol %, preferably less than 95 mol %, more preferably less than 92 mol %, still more preferably less than 90 mol %. Further, the saponification degree of the modified polyvinyl alcohol is, for example, 55 mol % or more, and is preferably 65 mol % or more, more preferably 70 mol % or more, still more preferably 80 mol % or more, particularly preferably 85 mol % or more from the viewpoint of, for example, the stability of the emulsion.

The protective colloid is used in any appropriate amount. The content of the protective colloid is preferably 0.1 part by weight or more, more preferably 0.5 part by weight or more, still more preferably 0.7 part by weight or more with respect to 100 parts by weight of the total of the monomer components. Further, the content of the protective colloid is preferably 10 parts by weight or less, more preferably 5 parts by weight or less, still more preferably 3 parts by weight or less, particularly preferably 2 parts by weight or less with respect to 100 parts by weight of the total of the monomer components. The protective colloid may be used in combination with the above-mentioned emulsifier, or only the protective colloid may be used without the use of the emulsifier. The above-mentioned emulsifier and the protective colloid are preferably used in combination. The emulsion polymerization may be performed in, for example, the following mode: water and the protective colloid are loaded in the polymerization vessel, and an emulsion obtained by mixing part or whole of the monomer composition with water and an emulsifier in advance to emulsify the composition is supplied to the polymerization vessel. When an anionic protective colloid (e.g., anion-modified polyvinyl alcohol) and the emulsifier are used in combination, at least one kind of emulsifier selected from the group consisting of: the anionic emulsifier; and the nonionic emulsifier is preferably used as the emulsifier from the viewpoint of the polymerization stability or the like.

In addition, any appropriate chain transfer agent may be used at the time of polymerization. Examples of the chain transfer agent include mercaptans, such as n-dodecylmercaptan, t-dodecylmercaptan, and thioglycolic acid. In addition, a chain transfer agent free of a sulfur atom (non-sulfur-based chain transfer agent) may be used. Specific examples of the non-sulfur-based chain transfer agent include: anilines, such as N,N-dimethylaniline and N,N-diethylaniline; terpenoids, such as α-pinene and terpinolene; styrenes, such as α-methylstyrene and an α-methylstyrene dimer; compounds each having a benzylidenyl group, such as dibenzylideneacetone, cinnamyl alcohol, and cinnamyl aldehyde; hydroquinones, such as hydroquinone and naphthohydroquinone; quinones, such as benzoquinone and naphthoquinone; olefins, such as 2,3-dimethyl-2-butene and 1,5-cyclooctadiene; alcohols, such as phenol, benzyl alcohol, and allyl alcohol; and benzyl hydrogens, such as diphenylbenzene and triphenylbenzene. The chain transfer agents may be used alone or in combination thereof. When the chain transfer agent is used, the content of the chain transfer agent is, for example, from 0.01 part by weight to 1 part by weight with respect to 100 parts by weight of the total of the monomer components.

### A-2. Additive

The liquid surface protective material for semiconductor wafer processing may further include any appropriate additive as required. Examples of the additive include a catalyst (e.g., a platinum catalyst), a tackifier, a plasticizer, a pigment, a dye, a filler, an age resistor, a conductive agent, a UV absorber, a light stabilizer, a peeling modifier, a softener, a flame retardant, a solvent, a leveling agent, a film forming aid, a thickener, a thixotropic agent, and an antifoaming agent. The additive is used in any appropriate amount in accordance with purposes.

### A-3. Method of Producing Liquid Surface Protective Material for Semiconductor Wafer Processing

The liquid surface protective material for semiconductor wafer processing may be produced by any appropriate method. For example, the acrylic emulsion resin and any additive may be added to and mixed with any appropriate solvent, or any additive may be added to and mixed with a solution obtained by subjecting the acrylic emulsion resin to emulsion polymerization. In addition, the acrylic emulsion resin may be used as it is. In addition, for example, ammonia water may be added to the acrylic emulsion resin to adjust its pH to from about 6 to about 8, or a material obtained by adding any appropriate solvent to adjust the concentration of the resin may be used as the liquid surface protective material.

Any appropriate solvent may be used as the solvent. Of those, an aqueous solvent is preferably used. Herein, the term “aqueous solvent” refers to water or a mixed solvent containing water as a main component (component to be incorporated at more than 50 wt %). An organic solvent that can be uniformly mixed with water may be used as the solvent for forming the mixed solvent except water. A specific example thereof is a lower alcohol. The organic solvents that can be uniformly mixed with water may be used alone or in combination thereof. A content ratio of water in the aqueous solvent is, for example, 90 wt % or more, preferably from 95 wt % to 100 wt %.

### B. Protective Film

The protective film of the embodiment of the present invention is formed by using the liquid surface protective material for semiconductor wafer processing described in the section A. The protective film is formed by, for example, applying the liquid surface protective material to the surface of the semiconductor wafer by any appropriate method, and then drying the applied protective material.

The thickness of the protective film is set to any appropriate value. The thickness may be set in accordance with, for example, the height of a protrusion of the semiconductor wafer surface on which the protective film is formed. The thickness of the protective film is, for example, from 50 μm to 500 μm, preferably from 100 μm to 300 μm, more preferably from 100 μm to 200 μm. When the thickness of the protective film falls within the above-mentioned ranges, the semiconductor wafer surface (e.g., the circuit surface) can be appropriately protected in a semiconductor wafer processing process. In addition, the protective film can be easily peeled off and removed without breakage after the processing of the semiconductor wafer.

A tensile modulus of elasticity of the protective film at 23° C. is preferably from 0.1 GPa to 1.1 GPa, more preferably from 0.12 GPa to 1.0 GPa, still more preferably from 0.13 GPa to 0.95 GPa. When the tensile modulus of elasticity of the protective film at 23° C. falls within the above-mentioned ranges, the protective film can be peeled with a tape peeling apparatus to be used for the peeling of a pressure-sensitive adhesive tape. Herein, the term “modulus of elasticity of the protective film at 23° C.” refers to a value measured by the following method. A protective film (film) having a thickness of 100 μm is cut into a size of 100 mm long by 25 mm wide, and is pulled with a precision universal tester (manufactured by Shimadzu Corporation, apparatus name: “AUTOGRAPH AG-IS”) at a chuck-to-chuck distance of 50 mm and a tensile rate of 300 mm/min. A stress change until the film undergoes plastic deformation is recorded to provide a stress-strain curve. The tensile modulus of elasticity is determined by linear regression of the curve between specified two strains 81=1 and 22=2. The above-mentioned measurement is performed with three test pieces cut out from different sites, and an average value thereof is defined as the tensile modulus of elasticity. The above-mentioned measurement is performed at 23° C. and 50% RH in conformity with JIS K 7161.

The pressure-sensitive adhesive strength of the protective film to a silicon wafer is preferably 1.0 N/25 mm or less, more preferably 0.8 N/25 mm or less, still more preferably 0.3 N/25 mm or less, particularly preferably 0.1 N/25 mm or less. The pressure-sensitive adhesive strength to the silicon wafer is, for example, 0.08 N/25 mm or more. When the pressure-sensitive adhesive strength to the silicon wafer falls within the above-mentioned ranges, the semiconductor wafer surface is appropriately protected in the semiconductor wafer processing process, and hence the protective film can be easily peeled off and removed after the processing process without damage to the semiconductor wafer surface. Herein, the term “pressure-sensitive adhesive strength to the silicon wafer” refers to the pressure-sensitive adhesive strength measured by the following method. A liquid surface protective material is applied to a mirror wafer (manufactured by Shin-Etsu Chemical Co., Ltd.) at a Wet coating thickness of 200 μm so as to have a length of 100 mm or more, and the resultant is dried at 80° C. for 5 minutes, followed by the formation of a protective film having a thickness of about 100 μm. After that, the resultant is left to stand still at 23° C. for 30 minutes. Next, a 180° peeling test is performed under the atmosphere at 23° C. and 50% RH, and under the condition of a tensile rate of 300 mm/min to measure the pressure-sensitive adhesive strength.

The pressure-sensitive adhesive strength of the protective film to a silicon wafer after immersion in water is preferably 0.7 N/25 mm or less, more preferably 0.3 N/25 mm or less, still more preferably 0.2 N/25 mm or less, particularly preferably 0.15 N/25 mm or less. The pressure-sensitive adhesive strength to the silicon wafer after immersion in water is, for example, 0.05 N/25 mm or more. When the pressure-sensitive adhesive strength to the silicon wafer after immersion in water falls within the above-mentioned ranges, the protective film can be suitably used in the semiconductor wafer processing process. Herein, the term “pressure-sensitive adhesive strength to the silicon wafer after immersion in water” refers to a pressure-sensitive adhesive strength measured by the following method. A liquid surface protective material is applied to a mirror wafer (manufactured by Shin-Etsu Chemical Co., Ltd.) at a Wet coating thickness of 200 μm so as to have a length of 100 mm or more, and the resultant is dried at 80° C. for 5 minutes, followed by the formation of a protective film having a thickness of about 100 μm. The silicon wafer having formed thereon the protective film is immersed in water at 23° C., and is then left for 30 minutes. Next, a 180° peeling test is performed under the atmosphere at 23° C. and 50% RH, and under the condition of a tensile rate of 300 mm/min to measure the pressure-sensitive adhesive strength.

### C. Method of Processing Semiconductor Wafer

A method of processing a semiconductor wafer of an embodiment of the present invention includes: applying the liquid surface protective material for semiconductor wafer processing to a surface of a semiconductor wafer on which a circuit pattern is formed, to form a protective film; grinding the surface of the semiconductor wafer on which the protective film is not formed; and peeling off and removing the protective film. As described above, the liquid surface protective material is excellent in property of embedding the semiconductor wafer surface. Accordingly, a gap between the semiconductor wafer and the protective film is hardly formed, and hence the occurrence of chipping or the like of the semiconductor wafer due to the entrance of water into the gap, and adhesion of a foreign matter can be suppressed. In addition, as described above, the protective film formed by using the liquid surface protective material is not required to be removed by being dissolved with a solvent, and hence can be peeled off and removed with, for example, a peeling apparatus to be used for the peeling of a pressure-sensitive adhesive tape. Accordingly, an environmental load through use of the solvent can be reduced. In addition, an adhesive residue (adhesion of a residue of the surface protective material) on the semiconductor wafer surface can be suppressed after the peeling.

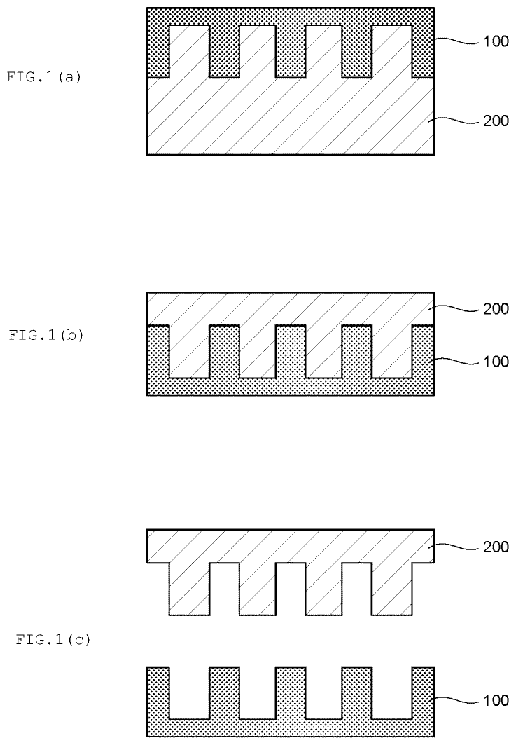

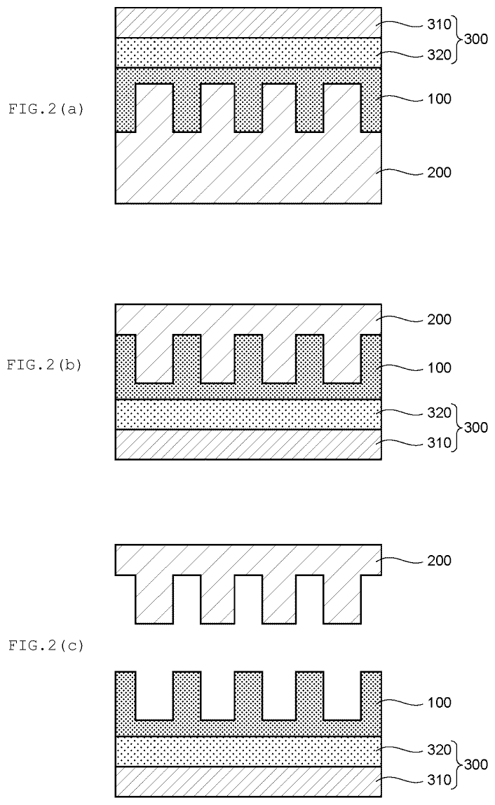

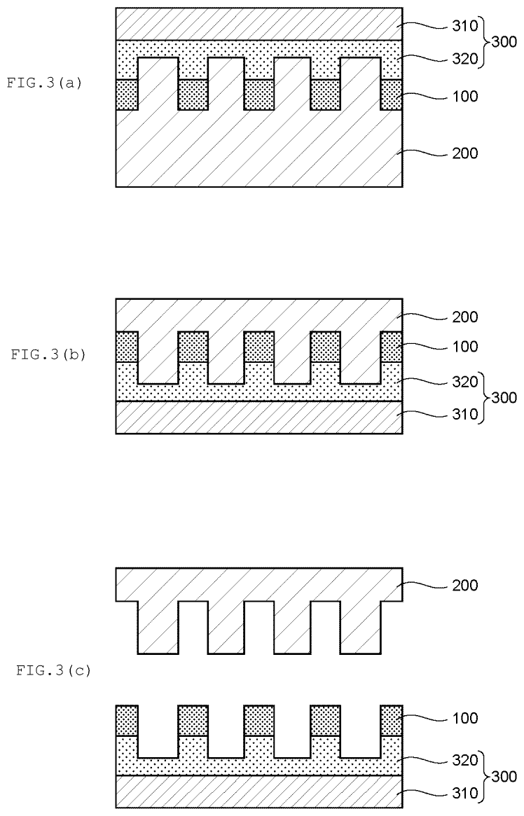

FIG. 1 to FIG. 3 are each a schematic sectional view of a semiconductor wafer and a protective film in a semiconductor wafer processing process of an embodiment of the present invention. In FIG. 1 to FIGS. 3, a protective film 100 and a semiconductor wafer 200 after a protective film formation step are illustrated in each of FIG. 1(a), FIG. 2(a), and FIG. 3(a), the protective film 100 and the semiconductor wafer 200 after a back surface grinding step are illustrated in each of FIG. 1(b), FIG. 2(b), and FIG. 3(b), and the protective film 100 and the semiconductor wafer 200 after the peeling off and removing are illustrated in each of FIG. 1(c), FIG. 2(c), and

FIG. 3(c). In the method of processing a semiconductor wafer of the embodiment of the present invention, the protective film 100 is formed so as to be brought into contact with the semiconductor wafer 200. As described above, the protective film 100 formed by using the liquid surface protective material is excellent in property of the semiconductor embedding wafer surface. Accordingly, for example, even a semiconductor wafer including a bump having a protrusion having a large height and a surface of the semiconductor wafer on which bumps are densely formed can be satisfactorily embedded with the material.

### C-1. Formation of Protective Film

The protective film may be formed by any appropriate method. The protective layer may be formed by, for example, applying the liquid surface protective material described in the section A to the surface of the semiconductor wafer, on which a circuit pattern is formed, by any appropriate method, and drying the applied protective material.

The protective film 100 may be used as described below. As illustrated in FIG. 1(a), the protective film 100 may be formed by applying a liquid surface protective material so that the material may embed a protrusion of a bump of the semiconductor wafer 200. Alternatively, as illustrated in FIG. 2(a) and FIG. 3(a), a liquid surface protective material may be applied to the semiconductor wafer 200 to form the protective film 100, and then a pressure-sensitive adhesive sheet 300 may be further bonded to the protective film 100 so that a pressure-sensitive adhesive layer 320 may be brought into contact with the protective film 100.

As a coating method, there are given, for example, spin coating, spray coating, ribbon coating, curtain coating, roller coating, coating with a brush, bar coater coating, air knife coating, gravure coating, gravure reverse coating, reverse roll coating, lip coating, die coating, dip coating, offset printing, flexo printing, and screen printing. Of those, spin coating, curtain coating, and spray coating are preferably used. When those methods are used, a property of embedding an unevenness of the semiconductor wafer surface can be further improved.

Any appropriate method is used as the drying method. Examples thereof include natural drying, blow drying, drying under reduced pressure, and heat drying. Of those, heat drying is preferably used. When the heat drying is performed, a heating temperature is, for example, from 30° C. to 100° C. In addition, a time period for the drying is, for example, from 1 minute to 60 minutes.

In the embodiments of further bonding the pressure-sensitive adhesive sheet 300 (embodiments of FIG. 2 and FIG. 3), the protective film 100 may be formed so as to have a thickness equal to or larger than the height of a protrusion of a bump (FIG. 2(a)), or may be formed so as to have a thickness smaller than the height of the protrusion of the bump (FIG. 3(a)). As illustrated in FIG. 2(a) and FIG. 3(a), when the liquid surface protective material and the pressure-sensitive adhesive sheet are used in combination, the thickness of the surface protective material can be made small, and hence the operation time (e.g., a time period for the drying of the protective film) can be shortened. In addition, in the back surface grinding step to be described later, the total thickness variation (TTV) of the semiconductor wafer can be alleviated. In addition, in the embodiments of FIG. 2(a) and FIG. 3(a), a portion of the semiconductor wafer surface on which the protective film is not formed in the application step may be thinly coated with the liquid surface protective material (not shown because the thickness is small). In this embodiment, a portion in which the pressure-sensitive adhesive layer 320 of the pressure-sensitive adhesive sheet 300 is directly brought into contact with the semiconductor wafer 200 is reduced, and hence an adhesive residue of the pressure-sensitive adhesive layer 320 on the surface of the semiconductor wafer 200 can be suppressed. The liquid surface protective material with which the semiconductor wafer surface has been thinly coated may be peeled from the semiconductor wafer surface together with the protective film 100 and/or the pressure-sensitive adhesive sheet 300 in a peeling step to be described later.

The pressure-sensitive adhesive sheet 300 typically includes a base material 310 and the pressure-sensitive adhesive layer 320. For example, any appropriate backgrinding tape may be used as the pressure-sensitive adhesive sheet. Specifically, a backgrinding tape capable of embedding the height of a protrusion free from being embedded with the protective film 100 may be used. The pressure-sensitive adhesive sheet preferably has a pressure-sensitive adhesive strength measured by a 180° peeling test to the protective film 100 of 2 N/25 mm or more. When the pressure-sensitive adhesive strength to the protective film 100 falls within the above-mentioned range, the semiconductor wafer can be appropriately held in the back surface grinding step, and the liquid surface protective material can be peeled without an adhesive residue in the peeling off and removal step.

### C-2. Back Surface Grinding

The back surface grinding (backgrinding) of the semiconductor wafer may be performed by any appropriate method (FIG. 1(b), FIG. 2(b), and FIG. 3(b)). A surface on which the circuit of the semiconductor wafer is not formed (a surface of the semiconductor wafer on which the protective film is not formed) is subjected to back surface grinding. The back surface grinding is generally performed while the water is cooled with water. As described above, the protective film formed by using the liquid surface protective material is excellent in embedding property. Accordingly, water is suppressed from entering a space between the semiconductor wafer and the protective film at the time of back surface grinding, and hence the occurrence of floating of the protective film and the occurrence of cracks on the semiconductor wafer can be suppressed.

### C-3. Peeling off and Removal

After the back surface grinding, the protective film is peeled off and removed from the semiconductor wafer at any appropriate stage (FIG. 1(c), FIG. 2(c), and FIG. 3(c)). As described above, the protective film formed by using the liquid surface protective material can be peeled off and removed, and hence the protective film is not required to be removed by being dissolved with a solvent such as an organic solvent. Accordingly, an environmental load through use of the solvent can be reduced. In addition, the protective film can be peeled off and removed with a peeling apparatus to be used for the peeling off and removal of a pressure-sensitive adhesive tape. Accordingly, the protective film may be used as it is in a production line for the semiconductor wafer using the pressure-sensitive adhesive tape such as a backgrinding tape.

### EXAMPLES

The present invention is specifically described below by way of Examples, but the present invention is not limited to these Examples. In addition, “part(s)” and “%” in Examples are by weight unless otherwise stated.

### [Synthesis Example 1] Synthesis of Acrylic Emulsion Resin

50 Parts by weight of ion-exchanged water and 1 part by weight of an anion-modified polyvinyl alcohol (manufactured by Mitsubishi Chemical Corporation, product name: “GOHSENX L-3266”) were added in a reaction vessel including a condenser, a nitrogen-introducing tube, a temperature gauge, and a stirring apparatus, and the alcohol was dissolved in the water at room temperature while a nitrogen gas was introduced, followed by an increase in temperature in the reaction vessel to 60° C. Next, 0.1 part by weight of a polymerization initiator (2,2′-azobis[N-(2-carboxyethyl)-2-methylpropionamidine]hydrate; Wako Pure Chemical Industries, Ltd., product name: “VA-057”) was added in the reaction vessel. Separately, a monomer composition formed of 65 parts by weight of n-butyl acrylate (BA), 25 parts by weight of acrylonitrile (AN), and 10 parts by weight of methyl methacrylate (MMA), 0.05 part by weight of a chain transfer agent (n-laurylmercaptan), and 2 parts by weight of an emulsifier (polyoxyethylene sodium lauryl sulfate; manufactured by Kao Corporation, product name: “LATEMUL E118B”) were added to 40 parts by weight of ion-exchanged water, and were mixed with a homomixer while the reaction vessel was purged with nitrogen. Thus, a monomer emulsion was obtained. The resultant monomer emulsion was loaded into the reaction vessel over 3 hours to perform an emulsion polymerization reaction. The resultant reaction mixture was aged by holding its temperature for an additional 3 hours. Next, the resultant was cooled to room temperature, and then 10% ammonium water was added to adjust its pH to 7.5. Thus, an acrylic emulsion resin was obtained.

### [Synthesis Examples 2 to 5] Synthesis of Acrylic Emulsion Resins

Acrylic emulsion resins were obtained in the same manner as in Synthesis Example 1 except that the monomer composition was changed as shown in Table 1.

### Examples 1 to 5

The following evaluations were performed by using the acrylic emulsion resins obtained in Synthesis Examples 1 to 5 as they were as liquid surface protective materials.

### Comparative Example

A water-soluble resin (manufactured by Japan Vam & Poval Co., Ltd., product name: “JC-25”) was dissolved in water so that the concentration of the resin became 20 wt %. Thus, a liquid surface protective material was obtained.

### <Evaluation>

The following evaluations were performed by using the liquid surface protection materials obtained in Examples and Comparative Example. The results are shown in Table 1.

### 1. Tensile Modulus of Elasticity

Each of the liquid surface protective materials was applied to a release-treated surface of a support subjected to release treatment to produce a film having a thickness of 100 μm. The resultant film was cut into a size of 100 mm long by 25 mm wide to provide a test piece. The test piece was pulled with a precision universal tester (manufactured by Shimadzu Corporation, apparatus name: “AUTOGRAPH AG-IS”) at a chuck-to-chuck distance of 50 mm and a tensile rate of 300 mm/min. A stress change until the test piece underwent plastic deformation was recorded to provide a stress-strain curve. A tensile modulus of elasticity was determined by linear regression of the curve between specified two strains ε₁=1 and ε₂=2. The above-mentioned measurement was performed with three test pieces cut out from different sites, and an average value thereof was defined as the tensile modulus of elasticity of each of the test pieces. The above-mentioned measurement was performed at 23° C. and 50% RH in conformity with JIS K 7161.

### 2. Pressure-sensitive Adhesive Strength

The liquid surface protective material was applied to a surface of a dummy wafer (manufactured by Shin-Etsu Chemical Co., Ltd.) so as to have a width of 25 mm and a thickness of 200 μm, and the resultant was dried to form a protective film. After that, the resultant was left to stand still at 23° C. for 30 minutes. Next, a 180° peeling test was performed under the atmosphere at 23° C. and 50% RH, and under the condition of a tensile rate of 300 mm/min to measure a pressure-sensitive adhesive strength.

Similarly, the liquid surface protective material was applied to a surface of a dummy wafer (manufactured by Shin-Etsu Chemical Co., Ltd.) so as to have a width of 25 mm and a thickness of 200 μm, and the resultant was dried to form a protective film. The dummy wafer having formed thereon the protective film was immersed in water at 23° C., and was left for 30 minutes. Next, a 180° peeling test was performed under the atmosphere at 23° C. and 50% RH, and under the condition of a tensile rate of 300 mm/min to measure a pressure-sensitive adhesive strength.

### 3. Embedding Property

The liquid surface protective material was applied to a surface of a silicon mirror wafer (8 inches, bump height: 75 μm, diameter: 90 μm, pitch: 200 μm) to form a protective film having a thickness of 200 μm. Adhesion states of the protective film and the wafer were observed by observing the wafer having formed thereon the protective a film with laser microscope (magnification: 100 times) from a side surface of the wafer. In addition, the dummy wafer having formed thereon the protective film was imaged from a surface on which the protective film had been formed, and the image was binarized (8-bit grayscale, brightness: 0 to 255, threshold: 114) with image analysis software (Image J (free software)). Five bumps were randomly selected, and the number of dots used for the display of one bump was counted. Evaluation was performed by marking a case in which the average number of dots for the five bumps was 600 or less with Symbol “o” (satisfactory), and marking a case in which the average number of dots was more than 600 with Symbol “x” (failure). An image of only a bump in a state of having no protective film formed thereon has 220 dots. When a protective film is formed, the number of dots becomes larger than 220. An average number of dots of 600 or less indicates that a property of embedding the unevenness of the wafer surface is excellent.

### 4. Adhesive Residue (Residue of Surface Protective Material) and Solder Drawing

A silicon wafer used for the evaluation of the pressure-sensitive adhesive strength was observed with a laser microscope after the peeling of the protective film. A case in which no adhesive residue (residue of the protective film) was present on the bumps was marked with Symbol “o” (satisfactory), and a case in which an adhesive residue (a residue of the protective film) was present on the bumps was marked with Symbol “x” (failure). In addition, a case in which no solder residue was observed on a semiconductor wafer surface was marked with Symbol “o” (satisfactory), and a case in which a solder residue was observed thereon was marked with Symbol “x” (failure).

### 5. Peelability

The surface protective material was applied to the silicon wafer so that its thickness after drying became 100 μm. Thus, a protective film was formed. The formed protective film was peeled from the silicon wafer with a hand. A case in which the protective film was able to be peeled without being torn was marked with Symbol “o” (satisfactory), and a case in which the protective film was broken during the peeling was marked with Symbol “x” (failure).

TABLE 1

| | | | | | | | Comparative |
|---|---|---|---|---|---|---|---|
| | | Example 1 | Example 2 | Example 3 | Example 4 | Example 5 | Example |
| Monomer composition | BA | 65 | 65 | 75 | 60 | 40 | Water-soluble |
| of acrylic emulsion | AN | 25 | 25 | 15 | 20 | — | resin |
| resin (parts by | Vac | — | — | — | — | 30 | |
| weight) | MMA | 10 | 8 | 10 | 20 | 30 | |
| | AA | 0 | 2 | — | — | — | |
| Evaluation | SP value ((cal/cm³)^{1/2}) | 10.3 | 10.4 | 9.8 | 10.1 | 9.4 | — |
| | Acid value (mg/KOH) | 0 | 9.4 | 0 | 0 | 0 | — |
| | Tensile modulus of | 0.25 | 0.31 | 0.13 | 0.95 | 0.39 | 0.24 |
| | elasticity (23° C.) (GPa) | | | | | | |
| | Pressure-sensitive | 0.15 | 0.8 | 0.12 | 0.09 | 0.11 | 0.18 |
| | adhesive strength to | | | | | | |
| | silicon wafer (23° C.) | | | | | | |
| | (N/25 mm) | | | | | | |
| | Pressure-sensitive | 0.09 | 0.15 | 0.11 | 0.07 | 0.16 | 0.80 |
| | adhesive strength to | | | | | | |
| | silicon wafer (after | | | | | | |
| | immersion in water) | | | | | | |
| | (N/25 mm) | | | | | | |
| | Embedding property | ∘ | ∘ | ∘ | ∘ | ∘ | ∘ |
| | Wafer adhesive residue | ∘ | ∘ | ∘ | ∘ | ∘ | ∘ |
| | Peelability | ∘ | ∘ | ∘ | ∘ | ∘ | x |
| | Solder drawing | ∘ | ∘ | ∘ | ∘ | ∘ | x |

BA: Butyl acrylate
AN: Acrylonitrile
Vac: Vinyl acetate
MMA: Methyl methacrylate
AA: Acrylic acid

The liquid surface protective materials for semiconductor wafer processing of Examples of the present invention were each excellent in embedding property. In addition, the protective film formed by applying the liquid surface protective material was able to be peeled off and removed, and adhesion of a residue of the protective film was suppressed.

### INDUSTRIAL APPLICABILITY

The liquid surface protective material for semiconductor wafer processing according to the embodiment of the present invention can be suitably used in a semiconductor wafer processing process.

### REFERENCE SIGNS LIST

100 protective film
200 semiconductor wafer
300 pressure-sensitive adhesive sheet
310 base material
320 pressure-sensitive adhesive layer

1. A liquid surface protective material for semiconductor wafer processing, comprising an acrylic emulsion resin.

2. The liquid surface protective material for semiconductor wafer processing according to claim 1, wherein the acrylic emulsion resin has an acid value of 10 mg/KOH or less.

3. The liquid surface protective material for semiconductor wafer processing according to claim 1, wherein the acrylic emulsion resin has a SP value of from 9 (cal/cm³)^{1/2} to 11 (cal/cm³)^{1/2}.

4. The liquid surface protective material for semiconductor wafer processing according to claim 1, wherein the liquid surface protective material for semiconductor wafer processing has a BH viscosity of from 0.1 Pa's to 10 Pa's.

5. A protective film formed by using the liquid surface protective material for semiconductor wafer processing of claim 1.

6. The protective film according to claim 5, wherein the protective film has a tensile modulus of elasticity at 23° C. of from 0.1 GPa to 1.1 GPa.

7. The protective film according to claim 5, wherein the protective film has a pressure-sensitive adhesive strength to a silicon wafer of 1.0 N/25 mm or less.

8. A method of processing a semiconductor wafer, the method comprising:
applying the liquid surface protective material for semiconductor wafer processing of claim 1 to a surface of a semiconductor wafer on which a circuit pattern is formed, to form a protective film;
grinding a surface of the semiconductor wafer on which the protective film is not formed; and
peeling off and removing the protective film.
